(19) United States
(12) Patent Application Publication
(10) Pub. No.: US 2004/0027209 A1
(43) Pub. Date: Feb. 12, 2004

(54) Fixed matching network with increased match range capabilities

(75) Inventors: Jin-Yuan Chen, Union City, CA (US); Frank F. Hooshdaran, Pleasanton, CA (US); Doug S. Jun, Cupertino, CA (US)

Correspondence Address: Patent Counsel, Applied Material, Inc., P.O. Box 450A, Santa Clara, CA, 95052, US

(73) Assignee: Applied Materials, Inc.

(21) Appl. No.: 10/379,306

(22) Filed: Mar. 3, 2003

Related U.S. Application Data
(60) Provisional application No. 60/402,405, filed on Aug. 9, 2002.

(51) Int. Cl. H03H 7/40

(52) U.S. Cl. 333/17.3; 333/32

(57) ABSTRACT

A matching network for performing frequency tuned matching between a source and a load. The matching network includes a first capacitor and first inductor, having fixed values, coupled in series from an input port to an output port. A second capacitor and second inductor, having fixed values, is coupled in series from one of the input port and output port to ground. The input port is adapted to receive a variable frequency RF signal and the output port is adapted to be coupled to a time-variant load impedance. The values of the first inductor and first capacitor are related by a first mathematical relationship, and the values of the second inductor and second capacitor are related by a second mathematical relationship. The substantial impedance range of the matching network enables a match to be maintained over a large fluctuation in load impedance.

### CROSS-REFERENCE TO RELATED APPLICATION

This patent application claims the benefit of U.S. Provisional Application, serial No. 60/402,405, filed Aug. 9, 2002, the contents of which are incorporated by reference herein.

### FIELD OF THE INVENTION

The invention relates to an impedance matching network for matching the impedance of a variable frequency radio frequency (RF) signal source to the time-variant impedance of a load and, more particularly, to broadband impedance matching networks.

### DESCRIPTION OF THE RELATED ART

Radio frequency (RF) matching networks are used for coupling RF power (e.g., 13.56 MHz) from an RF source having a substantially resistive impedance (e.g., 50 ohms) to a load having a complex, time-variant impedance. The matching network matches the source impedance to the load impedance to effectively couple RF power from the source to the load. In high power applications, such as, for example, coupling RF power to a plasma within a plasma reaction chamber of a semiconductor wafer processing system, among others, the matching network should be relatively efficient, i.e., the contribution of the matching network to the total loop resistance should be as small as possible.

During semiconductor wafer fabrication, a plasma is formed in a processing chamber to deposit materials on or etch materials from a workpiece, such as a semiconductor wafer. A gas is provided into the chamber and is ignited by an RF electromagnetic field to form a plasma. The electromagnetic field is formed by providing an RF signal from an RF source to a plasma generating element, such as a coil antenna or an electrode plate. The RF source is coupled to the plasma generating element via the matching network.

In particular, the reactive impedance of the plasma generating element and the plasma together form a load impedance for the source. However, fluctuations in plasma flux (i.e., the product of plasma density and charge particle velocity) cause the impedance of the load to change substantially during processing. For example, the impedance of the plasma load may illustratively increase by as much as twenty times (20×), depending on the process being performed and the type of chamber used to perform the process. Accordingly, matching the impedance of the RF source to the time-variant load impedance is difficult to maintain during wafer processing. Where proper impedance matching is not achieved during processing, the transfer of power from the source to the load becomes inefficient due to the power being reflected from the load and back to the source. Such inefficient power coupling impacts wafer processing throughput and may damage wafers and/or the wafer processing system components.

One type of matching network that is widely used in semiconductor wafer processing systems, is a tunable matching network wherein a series connected frequency-dependent passive element and a shunt connected frequency-dependent passive element are dynamically tuned to achieve an impedance match between the source and the load. One such tunable matching network is disclosed in commonly assigned U.S. Pat. No. 5,952,896 issued Sep. 14, 1999. This matching network comprises a series connected inductor and a shunt connected capacitor. A matching network controller mechanically tunes the capacitor and the inductor to achieve a match between the source and the load. As the load impedance changes, actuators must constantly alter the tunable elements of the inductor and capacitor to maintain the match. In environments where the load impedance is rapidly changing, mechanical tuning can not tune quickly enough to maintain an optimal match.

An alternative type of matching network that finds use when load impedances are rapidly varying is a fixed matching network with frequency tuning. The fixed matching network uses fixed valued elements, e.g., non-tunable capacitors and inductors. The elements may be tunable to achieve a nominal value, but they are not tuned during match operation to maintain the match as the load impedance changes. As such, the component values are selected to obtain a match from source to load impedance under nominal operating conditions, e.g., a nominal load impedance and a nominal source frequency. As the load impedance varies during wafer processing, the frequency of the RF source is tuned to maintain a match between the source and the load. In effect, the matching process is electronically tuned, and can maintain a match during rapid fluctuations in load impedance.

The fixed match is usually designed with an inductor or capacitor coupled in series between the power source and the biasing element, and in parallel from the source to ground. As described above, the components of the matching network are constant. When using a dual element matching network, e.g., an inductor in series and a capacitor in parallel, the range of impedance that the network can operate over is rather narrow. As such, the frequency tuning cannot achieve a match over a wide range of impedance fluctuations.

For example, in one prior art matching network a single inductor is connected in series between the source and the load, and a single capacitor is connected as a shunt with respect to the source and ground. As illustrated below, the matching range is very narrow, since it is only dependent on the frequency tuning range of the RF power generator. Specifically, the matching range is ΔZ/Zₒ=2Δω/ωₒ<20%, where Zₒ is the matching impedance at frequency ω₀, and the RF power generator frequency tuning is from (ωₒ−Δω) to (ωₒ+Δω), and where ωₒ=the center frequency.

FIGS. 4A-4H depict schematic diagrams of various embodiments of prior art impedance matching networks 420. Specifically, each exemplary matching network embodiment is illustratively coupled between a RF source 412 to a load 450, such as a capacitive type load or and inductive type load. FIGS. 4A and 4C depict schematic diagrams of fixed matching networks utilizing a series inductor and a shunt capacitor, while FIGS. 4B and 4D depict schematic diagrams of fixed matching networks utilizing a series capacitor and a shunt capacitor. FIGS. 4E and 4G depict schematic diagrams of fixed matching networks utilizing a series inductor and a shunt inductor, while FIGS. 4F and 4H depict schematic diagrams of fixed matching networks utilizing a series capacitor and a shunt inductor.

Referring to the embodiment of FIG. 4A, a radio frequency (RF) source 412 is first coupled in parallel to a shunt capacitor Cₛₕᵤₙₜ to ground 440, and the shunt capacitor Cₛₕᵤₙₜ is coupled to a series inductor Lₛₑᵣᵢₑₛ, which is coupled to a capacitive type impedance load Z_{L} 450, where Z_{L}=x−jy. Referring to the embodiment of FIG. 4B, an RF source 412 is first coupled in parallel to a shunt capacitor Cₛₕᵤₙₜ to ground 440, and the shunt capacitor Cₛₕᵤₙₜ is coupled to a series capacitor Cₛₑᵣᵢₑₛ, which is coupled to an inductive type impedance load Z_{L} 450, where Z_{L}=x+jy. Referring to the embodiment of FIG. 4C, an RF source 412 is first coupled in series to an inductor Lₛₑᵣᵢₑₛ, which is further coupled to a capacitive type impedance load Z_{L} 450, where Z_{L}=x−jy, and a shunt capacitor Cₛₕᵤₙₜ is coupled in parallel with the impedance load Z_{L} 450 to ground 440. Referring to the embodiment of FIG. 4D, an RF source 412 is first coupled in series to a capacitor Cₛₑᵣᵢₑₛ, which is further coupled to an inductive type impedance load Z_{L} 450, where Z_{L}=x+jy, and a shunt capacitor Cₛₕᵤₙₜ is coupled in parallel with the impedance load Z_{L} 450 to ground 440.

Referring to the embodiment of FIG. 4E, a radio frequency (RF) source 412 is first coupled in parallel to a shunt inductor Lₛₕᵤₙₜ to ground 440, and the shunt inductor Lₛₕᵤₙₜ is coupled to a series inductor Lₛₑᵣᵢₑₛ, which is coupled to a capacitive type impedance load Z_{L} 450, where Z_{L}=x−jy. Referring to the embodiment of FIG. 4F, an RF source 412 is first coupled in parallel to a shunt inductor Lₛₕᵤₙₜ to ground 440, and the shunt inductor Lₛₕᵤₙₜ is coupled to a series capacitor Cₛₑᵣᵢₑₛ, which is coupled to an inductive type impedance load Z_{L} 450, where Z_{L}=x+jy. Referring to the embodiment of FIG. 4G, an RF source 412 is first coupled in series to an inductor Lₛₑᵣᵢₑₛ, which is further coupled to a capacitive type impedance load Z_{L} 450, where Z_{L}=x−jy, and a shunt inductor Lₛₕᵤₙₜ is coupled in parallel with the impedance load Z_{L} 450 to ground 440. Referring to the embodiment of FIG. 4H, an RF source 412 is first coupled in series to a capacitor Cₛₑᵣᵢₑₛ, which is further coupled to an inductive type impedance load Z_{L} 450, where Z_{L}=x+jy, and a shunt inductor Lₛₕᵤₙₜ is coupled in parallel with the impedance load Z_{L} 450 to ground 440.

Referring to the prior art embodiment of FIG. 4A, for the series connected inductor Lₛₑᵣᵢₑₛ, the impedance range is 2ΔωL when the RF power source is frequency-tuned from (ωₒ−Δω) to (ωₒ+Δω), where ω=2πf, and L=inductance, as measured in Henry. Using a numerical example, if the frequency is tunable from 1.9 MHz to 2.1 MHz and the inductance Lₛₑᵣᵢₑₛ is 10 uH, the range of impedance available is only 12.56 ohms. Similarly, for the parallel connected capacitor Cₛₕᵤₙₜ, the impedance range is

$$\frac{2 Δω}{( {ω}_{o}^{2} - Δ ω ) {C}_{s h u n t}} ,$$

when the RF power source is frequency-tuned from (ωₒ−Δω) to (ωₒ+Δω), where ω=2πf, and C=capacitance, as measured in Farads. Using a numerical example, if the frequency is tunable from 1.9 MHz to 2.1 MHz and the capacitance is 500 pf, the range of impedance available is only 15.97 ohms. It is noted that similar numerical examples and analyses are also applicable for the matching network configurations shown in FIGS. 4B through 4H. As such, when such a fixed matching network with frequency tuning is utilized, the match range is very narrow as compared to the wide process window (i.e., wide fluctuations in the load impedance).

Therefore, there is a need for an improved fixed matching network with frequency tuning that is capable of providing a wide range of impedance matching for time-variant impedance loads.

### SUMMARY OF THE INVENTION

The present invention is a matching network for performing frequency tuned matching between a source and a load. The matching network includes a first capacitor and first inductor, having fixed values, coupled in series from an input port to an output port. A second capacitor and second inductor, having fixed values, is coupled in series from one of the input port and output port to ground. The values of the first inductor and first capacitor are related by a first mathematical relationship, and the values of the second inductor and second capacitor are related by a second mathematical relationship.

The input port is adapted to receive a variable frequency RF signal and the output port is adapted to be coupled to a time-variant load impedance. The substantial impedance range of the matching network enables a match to be maintained over a large fluctuation in load impedance. One specific application for the matching network is in a plasma enhanced, semiconductor wafer processing system, where the matching network efficiently couples RF energy to a plasma.

### BRIEF DESCRIPTION OF THE DRAWINGS

So that the manner in which the above recited features of the invention are attained can be understood in detail, a more particular description of the invention, briefly summarized above, may be had by reference to the embodiments thereof, which are illustrated in the appended drawings. It is to be noted, however, that the appended drawings illustrate only typical embodiments of this invention, and are therefore, not to be considered limiting of its scope, for the invention may admit to other equally effective embodiments.

FIG. 1 depicts a schematic, cross sectional view of a semiconductor processing system in which the embodiments of the impedance matching networks of the present invention can be utilized;

FIGS. 2A-2H depict schematic diagrams of various embodiments of impedance matching networks of the present invention;

FIG. 3 depicts a table comparing the various embodiments of impedance matching networks of the present invention of FIGS. 2A-2H with respect to the various embodiments of prior art impedance matching networks of FIGS. 4A-4H; and

FIGS. 4A-4H depict schematic diagrams of various embodiments of prior art impedance matching networks.

To facilitate understanding, identical reference numerals have been used, where possible, to designate identical elements that are common to the figures.

### DETAILED DESCRIPTION

The present invention is a wide range, frequency tuned, fixed matching network (referred to herein as a WRFT network) to be used, for example, to couple RF energy to a plasma in a semiconductor wafer processing reactor. The WRFT network provides a wide dynamic range of impedance values for matching a tunable frequency source to a time-variant load impedance. The load impedance is generally defined by a plasma and an associated plasma generating element in a plasma enhanced semiconductor wafer processing reactor. The plasma generating element may be an electrode in a capacitively coupled-type reactor or an antenna in an inductively coupled-type reactor. As shown and discussed in further detail below, the matching range of the present invention is defined by the relationship

$$\frac{Δ Z}{{Z}_{o}} \approx ( 2 n - 1 ) ( \frac{2 Δ ω}{{ω}_{o}} ) ,$$

where n=a number greater than one (1), and the matching range increases by approximately (2n−1) times.

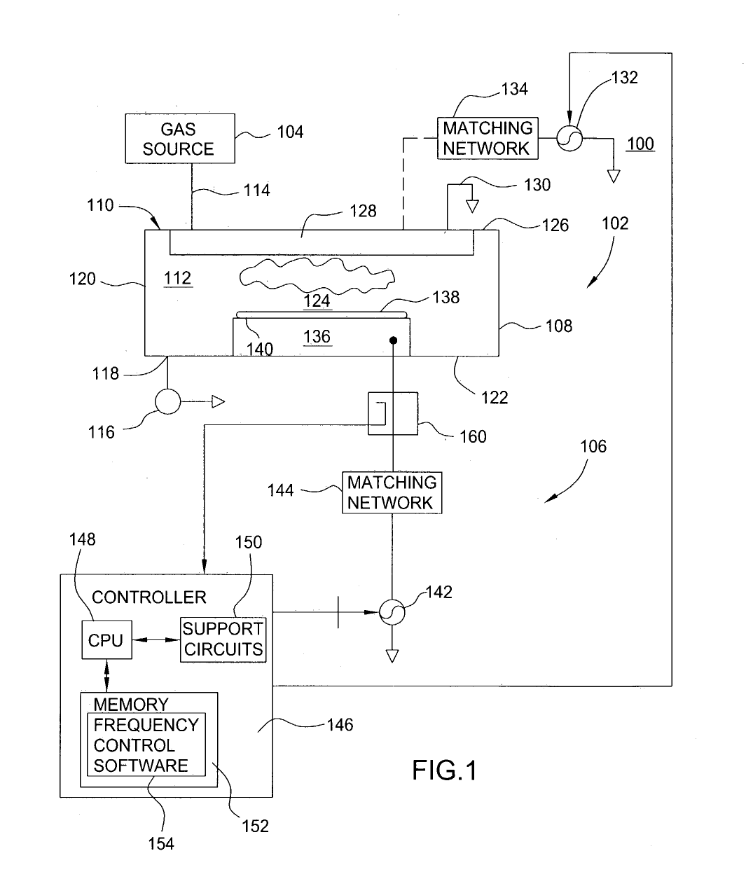

FIG. 1 depicts a schematic cross sectional view of a plasma enhanced, semiconductor wafer processing system 100 in which a matching network (WRFT network) of the present invention may be utilized. The illustrative system 100 can be used during integrated circuit fabrication, such as a reactive ion etching process. The inventive WRFT network, such as matching networks 134 and/or 144, finds use in any wafer processing system where the load impedance may change rapidly enough to make mechanical tuning of the matching network impractical. Such systems may include those that perform plasma enhanced chemical vapor deposition, physical vapor deposition, plasma annealing and the like.

The system 100 generally comprises a reaction chamber (reactor) 102, a gas source 104, vacuum pump 116, and drive electronics 106. The reactor 102 comprises a chamber body 108 and a lid assembly 110 that defines an evacuable chamber 112 for performing substrate processing. In one embodiment, the reactor 102 may be a Dielectric Etch eMax reactor, available from Applied Materials, Inc. of Santa Clara, Calif. A detailed description of an eMax system is contained in U.S. patent application Ser. No. 10/146,443, filed May 14, 2002, the contents of which is incorporated by reference herein in its entirety.

The gas source 104 is coupled to the reactor 102 via one or more gas lines 114 for providing process gases such as etchant gases, purge gases or deposition gases. The vacuum pump 116 is coupled to the reactor 102 via an exhaust port 118 for maintaining a particular pressure in the reactor and exhausting undesirable gases and contaminants.

The chamber body 108 includes at least one sidewall 120 and a chamber bottom 122. In one embodiment, the at least one sidewall 120 has a polygon shaped (e.g., octagon or substantially rectangular) outside surface and an annular or cylindrical inner surface. Furthermore, the sidewall 120 is generally electrically grounded. The chamber body 108 may be fabricated from a non-magnetic metal, such as anodized aluminum, and the like. The chamber body 108 contains a substrate entry port that is selectively sealed by a slit valve (not shown) disposed in the processing platform.

The lid assembly 110 is disposed over the sidewalls 120 and defines a processing region 124 within the reactor 102. The lid assembly 110 generally includes a lid 126 and may contain a plasma generating element (e.g., an electrode) 128 mounted to the lid 126. The lid 126 may be fabricated from a dielectric material such as aluminum oxide (Al₂O₃), or a non-magnetic metal such as anodized aluminum. The plasma generating element 128 is fabricated from a conductive material such as aluminum, stainless steel, and the like. The plasma generating element 128 may also function as a showerhead for dispensing gases into the processing region 124.

The plasma generating element 128 may be coupled to ground 130 (i.e., not used in certain applications). Alternatively, the element 128 may be coupled to a high frequency RF power source 132 via a matching network 134 of the present invention. The high frequency power source (top power source) 132 provides RF power in a range between about 0.5 Watts to 10,000 Watts at a center frequency ωₒ=2πfₒ, where the center frequency fₒ is in a range of about 200 KHz to 150 MHz. The high frequency power source 132 is used to ignite and maintain a plasma from a gas mixture in the chamber 106.

A substrate support pedestal 136 is disposed within the chamber 112 and is seated on the chamber bottom 122. A substrate (i.e., wafer) 138 undergoing wafer processing is secured on an upper surface 140 of the substrate support pedestal 136. The substrate support 136 may be a susceptor, a heater, ceramic body, or electrostatic chuck on which the substrate is placed during processing. The substrate support pedestal 136 is adapted to receive an RF bias signal, such that the substrate support pedestal serves as a biasing element (e.g., cathode electrode). Specifically, the pedestal 136 contains a component that is either a dedicated electrode or is a conductive component that can be used as an electrode such as a cooling plate.

Within the drive electronics 106, a bias power source 142 is coupled via a matching network (a WRFT network) 144 of the present invention to the pedestal 136. In one embodiment, the grounded sidewalls 122 and the plasma generating element 128 together define an anode with respect to the biasing element (cathode) in the substrate support pedestal 120. In particular, the bias power source 142 provides RF power in the range of about 0.5 Watts to 10,000 Watts (W) and at a center frequency (fₒ) in the range of about 200 KHz to 150 MHz. In one specific embodiment, the bias power source 142 provides RF power in a range of about 10 Watts to 5000 Watts (W), and at a frequency in the range of about 200 KHz to 30 MHz.

A controller 146 may be utilized to control the bias power source 142 as well as control the high frequency RF power source 132. The controller 146 comprises a central processing unit (CPU) 148, support circuits 150, and a memory 152. The CPU 148 is generally a microprocessor that performs general computer functions in accordance with programming stored in the memory 152. However, the CPU may also be an application specific integrated circuit, a field programmable gate array, and the like that is capable of controlling the frequency of the RF sources 132 and 142. The support circuits are well-known circuits such as clocks, power supplies, cache, input/output drivers, and the like. The memory 152 may be random access memory, read only memory, floppy disks, hard disks, or any combination thereof. The memory 152 stores frequency control software 154 that is executed by the CPU 148 to control the frequency of the power sources 142 and 132 and maintain a match between the load and the source. The control function is generally closed loop control whereby the controller 146 monitors the reflected power from the load and adjusts the frequency of the source to minimize the reflected power. In one embodiment, the reflected power is monitored using a directional coupler 160.

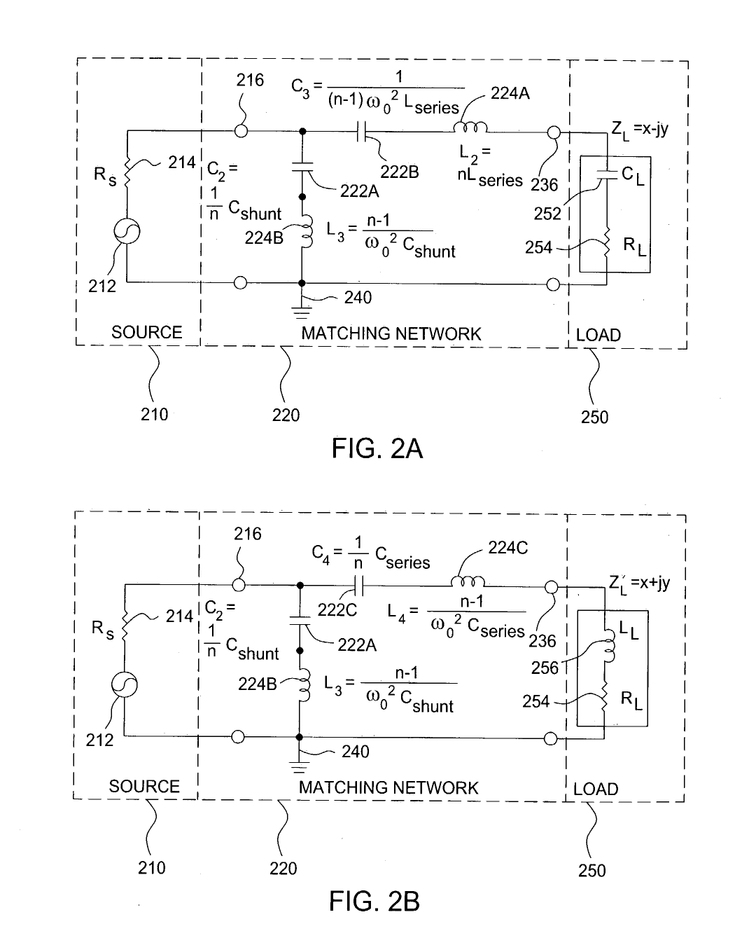

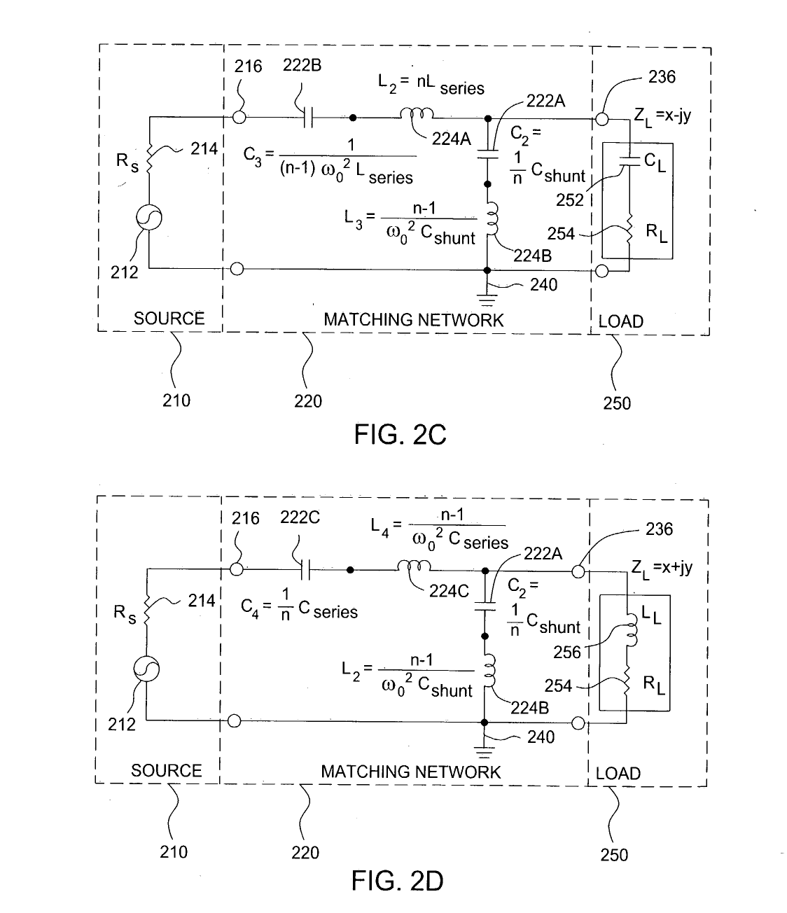

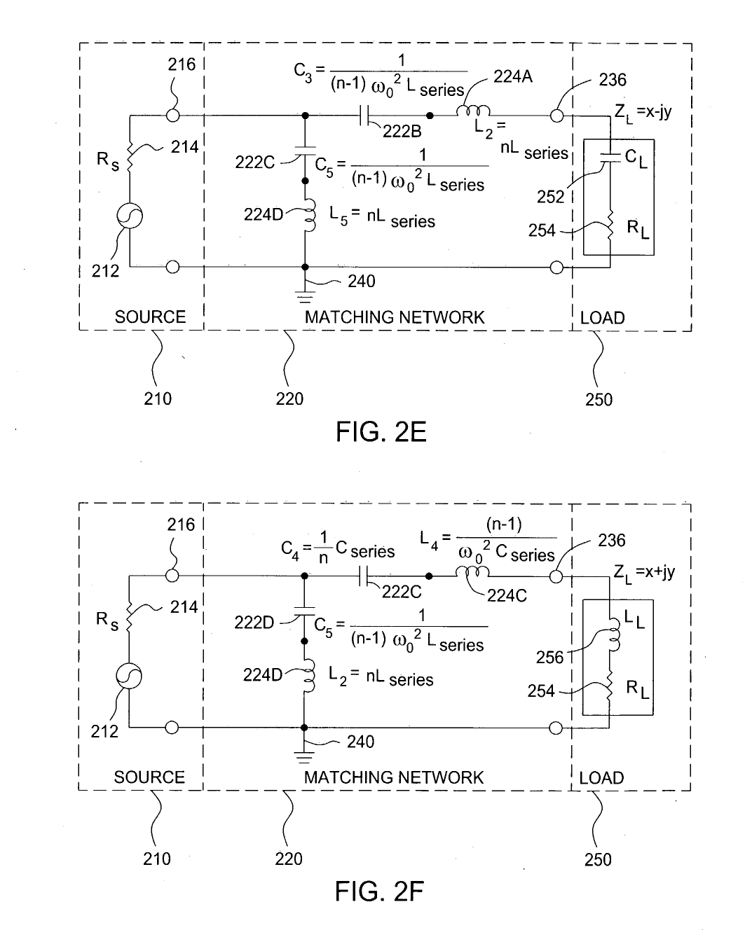

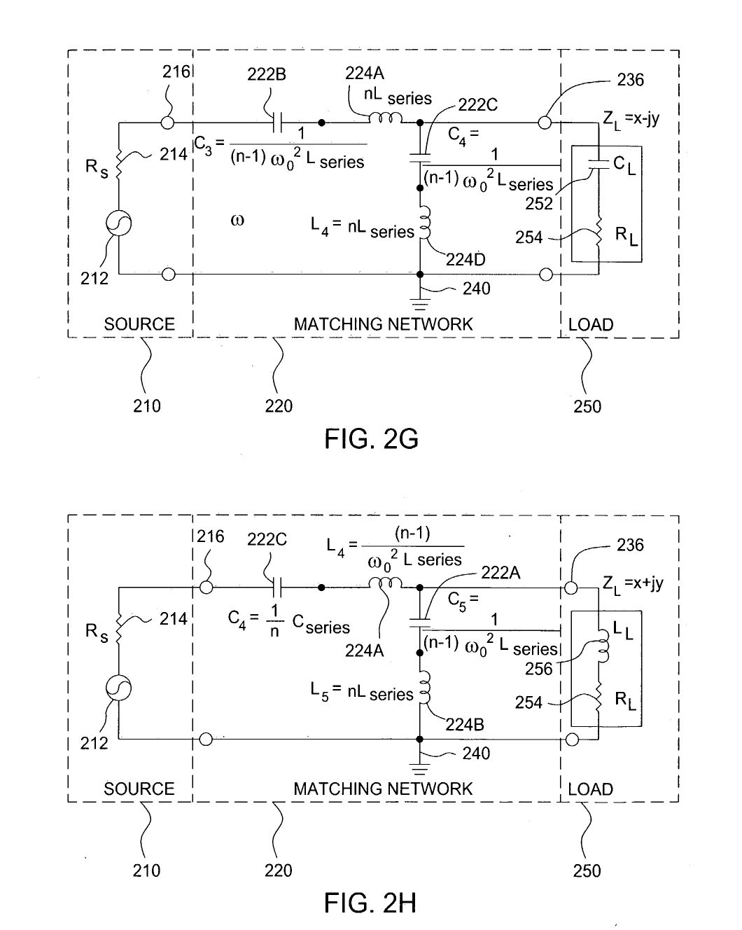

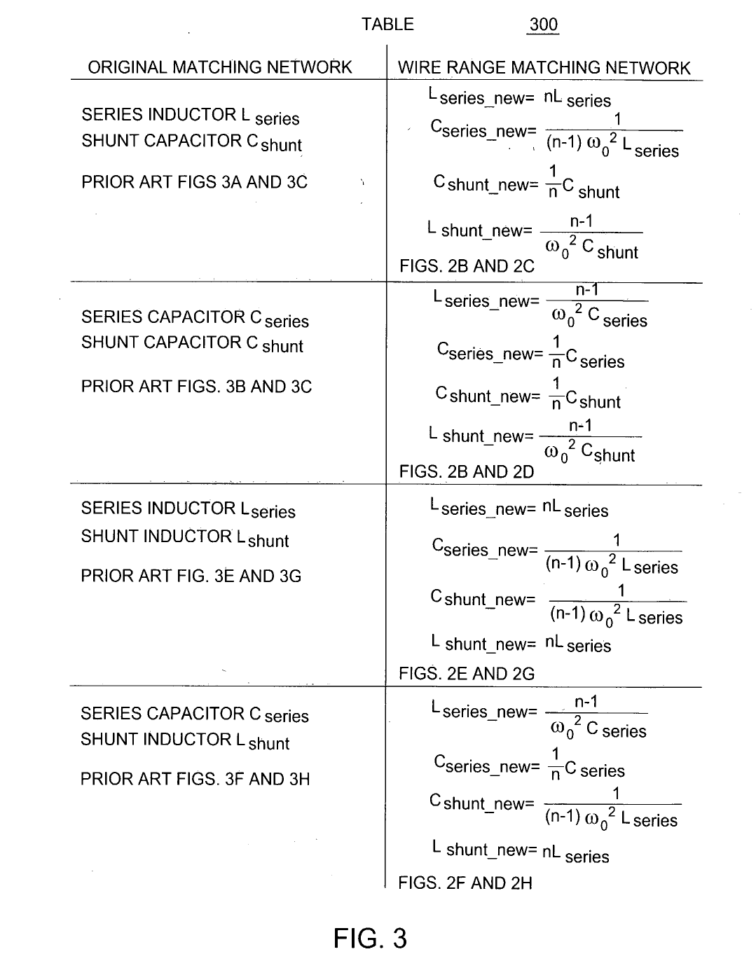

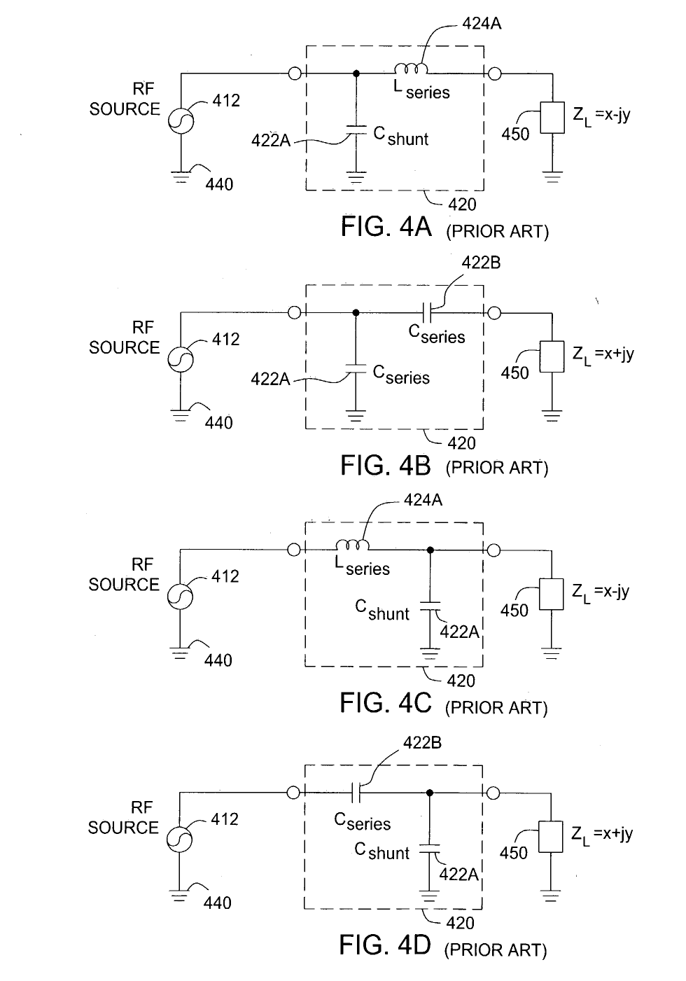

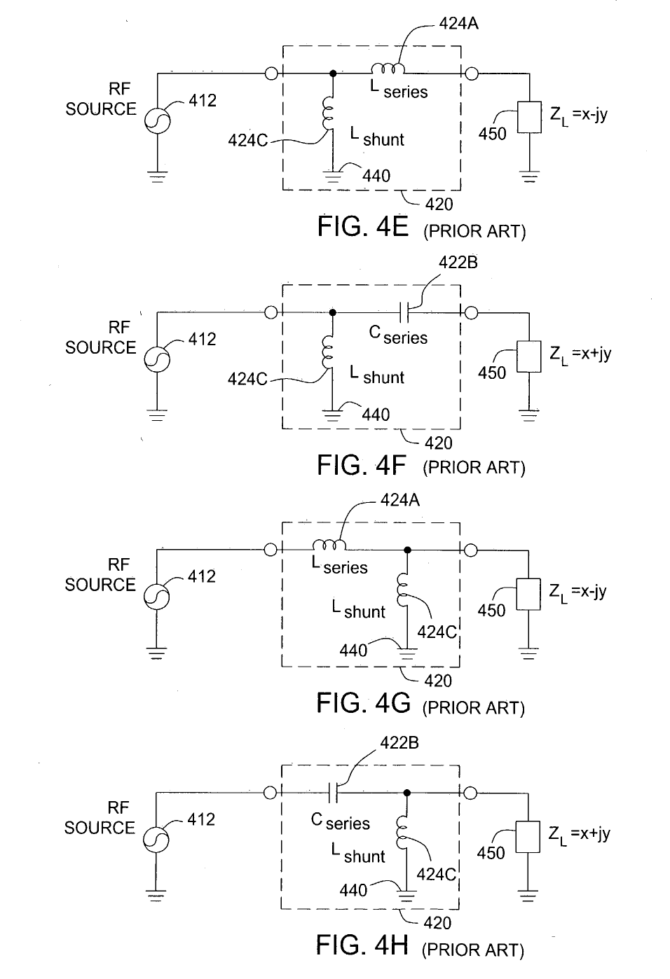

FIGS. 2A-2H depict schematic diagrams of various embodiments of impedance matching networks 220 of the present invention. The impedance matching networks 220 are used for coupling RF power from an RF source 210 to a load 250. The circuit 200 illustratively represents a plasma reactor as the load 250 that is used to facilitate semiconductor wafer processing. However, those skilled in the art will recognize that the various embodiments of the matching network may be for other high power applications, such as coupling RF or microwave power to an antenna within a communications system, among others. As discussed below, these illustrative embodiments have a matching range that increases by approximately (2n−1) times over the prior art configurations shown in FIGS. 4A-4H.

For each of the embodiments shown in FIGS. 2A-2H, the RF source 210 is represented by an AC signal source 212 connected to a series resistance Rₛ 214 (e.g., 50 ohms). Further, the load 250, for example, is a time-variant, complex impedance, such as a plasma within a plasma reaction chamber of a semiconductor wafer processing system of FIG. 1. FIGS. 2A, 2C, 2E, and 2G illustrate embodiments of a capacitively coupled reactor, where the instantaneous load impedance Z_{L}=x−jy is modeled as a capacitor C_{L} 252 connected to a series resistance R_{L} 254. Alternatively, FIGS. 2B, 2D, 2F, and 2H illustrate embodiments of an inductively coupled type reactor, where the instantaneous load impedance Z_{L}=x+jy is modeled as an inductor L_{L} 256 connected to a series resistance R_{L} 254. In either of the capacitively coupled or inductively coupled type reactor embodiments, the matching network 220 of the present invention matches the source impedance to the load impedance, such that fluctuations in the load impedance during wafer processing will not result in diminished power coupling efficiency.

Referring to FIG. 2A, the matching network 220 comprises a shunt capacitor C₂ 222A, a series inductor L₂ 224A, a series capacitor C₃ 222B, and a shunt inductor L₃ 224B, where the matching network 220 is coupled between a terminal 216 at the source 210 and a terminal 236 at the load 250. Specifically, a first end and a second end of the shunt capacitor C₂ 222A are respectively coupled to the terminal 216 and a first end of the shunt inductor L₃ 224B. A second end of the shunt inductor L₃ 224B is coupled to ground 240, such that the serially coupled shunt capacitor C₂ 222A and inductor L₃ 224B are parallel to the source 212, which is also coupled to ground 240. Additionally, a first end and a second end of the series capacitor C₃ 222B are respectively coupled to the terminal 216 and a first end of the series inductor L₂ 224A. A second end of the series inductor L₂ 224A is coupled to the load 250 at terminal 236, such that the serially coupled serial capacitor C₃ 222B and inductor L₂ 224A are serially coupled to the load 250, which is further coupled to ground 240.

A person skilled in the art for which the invention pertains will appreciate that the network 220 also includes a match (or loop) resistance (not shown), which represents the cumulative resistive losses in all component circuitry within the network 220. However, the match resistance is very low (e.g., 0.01 ohms to 5 ohms) and considered negligible as compared to the overall impedance value of the network 220, and is only mentioned for completeness of understanding the invention.

The illustrative embodiments shown in FIGS. 2A-2D provide load impedance matching by tuning the frequency of the source 210. As discussed in further detail below, FIGS. 2A-2H represent improved matching networks 220 over the respective prior art networks 420 shown in FIGS. 4A-4H. Referring to FIG. 2A, the inductor L₂ 224A is provided with an inductance value “nL”, where “n” is a number greater than one (1). The new inductance value for inductor L₂ 224A is “n” times an inductance value “L” of a matching network having just a single series inductor, such as the single series inductor Lₛₑᵣᵢₑₛ 424A of FIG. 4A having the value “L”. Further, the capacitor C₃ 222B is added in series with the inductor L₂ 224A, where the capacitor C₃ 222B has an impedance value equal to the original impedance value of the single inductor Lₛₑᵣᵢₐₗ (FIG. 4A) having a value “L”, where Cₛₑᵣᵢₑₛ=1/(n−1)ωₒ²Lₛₑᵣᵢₑₛ, and ωₒ is a center frequency of the RF signal provided by the source 210. The combination of the serial coupled capacitor C₃ 222B and inductor L₂ 224A in the matching network 220 is capable of providing an impedance range that is increased up to approximately (2n−1) times the original range of the impedance range of a single series inductor used in the prior art matching network 420 of FIG. 4A. As such, for a given component value in an existing matching network design, an improved network can be derived by replacing the series inductor Lₛₑᵣᵢₑₛ of a prior art matching network with a combination of a capacitor and an inductor (e.g., C₃ and L₂) each having selective values, as discussed below in further detail. The result is a matching network with an increased impedance range.

The same principle also applies for a single shunt element (capacitor or inductor) of the matching network 220. The impedance ranges of matching networks 220 can be improved to have an increased impedance range by replacing the single element with a pair of elements having appropriate values. For example, the shunt capacitor Cₛₕᵤₙₜ of FIG. 4A is replaced with a shunt capacitor C₂ 222A, which is serially coupled to shunt inductor L₃ 224B of FIG. 2A. In particular, the capacitor C₂ 222A is provided with a new capacitance value

$$\frac{1}{n} {C}_{s h u n t} ,$$

where “n” is a number greater than one (1), as well as the same value as used in the serial leg (elements 222B and 224A) of the network 220. The new capacitance value C₂ is 1/n times the capacitance value “C” of a matching network having just a single series capacitor, such as Cₛₕᵤₙₜ 424A of FIG. 4A having the value “C”. Further, the inductor L₃ 224B is coupled in series with the capacitor C₂ 222A, where the inductor L₃ 224B has an impedance value equal to the original impedance value of the single capacitor Cₛₕᵤₙₜ (FIG. 4A) having a value “C”, where L₃=n−1/ωₒ²Cₛₕᵤₙₜ, and ωₒ is a center frequency of the RF signal provided by the source 210.

In the prior art matching networks having only a single series coupled inductor “Lseries” and a single shunt capacitor “CCshunt” as shown in FIG. 4A, the single series coupled inductor Lₛₑᵣᵢₑₛ may be defined as having an impedance of Z and an absolute impedance range of |ΔZ|. In particular, for

ωₒ, Z=jωₒL;

(ωₒ−Δω), Z=j*ωₒ−Δω)L; and

(ωₒ+Δω), Z=j(ωₒ+Δω)L;

where ωo=2πfₒ at an initial frequency, Δω=a change in frequency, and L=inductance as measured in Henries. As such, the impedance range |ΔZ|=2ΔωL.

By illustration, a 10 μH inductor that is serially coupled between a source 210 and load 250, where the source 210 illustratively provides a 2 MHz, +/−100 KHz signal, has an impedance of 125.6 ohms and an absolute impedance range of 12.56 ohms. Specifically,

jωₒL=(2π)(2×10⁶)(10×10⁻⁶)=125.6 ohms

ΔZ_{@1.9 MHZ and 2.1 MHZ}=(2π)(2×10⁶)(10×10⁻⁶)(2.1−1.9)=12.56 ohms.

The exemplary embodiment shown in FIG. 2A increases this absolute impedance range by at least a factor of (2n−1). For example, where the original inductance is increase by a factor of n=2, the absolute impedance range increases by at least a factor of three ((2)(2)−1)=3. Specifically, the inductance of inductor L₂ 224A is “2L” and the capacitor C₃ 222A is selected to have the same impedance as the original impedance, illustratively using the single inductor. For

$$\begin{matrix}( {ω}_{o} - Δω ) , Z = ( j ( {ω}_{o} - Δ ω ) 2 L ) - j ( \frac{{ω}_{o}^{2} L}{{ω}_{o} - Δ ω} ) ; \\ ( {ω}_{o} - Δω ) , Z = ( j ( {ω}_{o} + Δ ω ) 2 L ) - j ( \frac{{ω}_{o}^{2} L}{{ω}_{o} + Δ ω} ) ; \\ Accordingly , \vert Δ Z \vert = ( 4 Δ ω L ) + ( \frac{2 {ω}_{o}^{2} Δ ω L}{( {ω}_{o} + Δ ω ) ( {ω}_{o} - Δ ω )} ) .\end{matrix}$$

Such results provides an increased impedance range of up to three times (3×) the impedance range of the original impedance range provided by a single inductor. By illustration, the inductor L₂ 224A is provided with a inductance value of 20 uH (i.e., twice the inductance value of the illustrative single inductor Lₛₑᵣᵢₑₛ described above. The value of the capacitor C₃ 222A is calculated such that the embodiment absolute impedance is equal to the impedance of the original impedance Lₛₑᵣᵢₑₛ at ωₒ. As such, the required capacitance is computed as:

C=1/(n−1)107 ₒ²Lₛₑᵣᵢₑₛ=1/(2−1)((2π)(2×10⁶))²(10×10⁻⁶)=634 pF,

where Lₛₑᵣᵢₑₛ =the inductance value of the original single series inductor as illustratively shown in FIG. 3A.

Computing for the impedances at 2 MHz +/−100 Khz, the result is

$$Z @ 2 MHz = {Z}_{c} + {Z}_{L} = - ( \frac{1}{( 2 π ) ( 2 {x10}^{6} ) ( 634 {x10}^{- 12} )} ) + ( ( 2 π ) ( 2 {x10}^{6} ) ( 20 {x10}^{- 6} ) ) = 125.62 Ω$$

Similarly,

Z@2.1 MHz=−119.6+263=144.16 Ω

Z@1.9 MHz=−132.19+238.64=106.45 Ω

|ΔZ|=144.16−106.45=37.71 Ω

Thus, impedance range has increased by a factor greater than three (>3). In particular, the serial coupled elements (inductor L₂ and capacitor C₃) forming a serial “leg” between terminals 216 and 236 of the matching circuit shown in FIG. 2A has an impedance range of 37.71 ohms, as compared to a single inductor (e.g., Lₛₑᵣᵢₑₛ), which has an impedance range of merely 12.56 ohms.

A similar analysis may be performed for the matching network circuit 200 where the inductor L₂ 224 has an inductance increased three times (i.e., from L to 3L), while the capacitor C₃ has a value selected to provide an impedance value equal to the impedance of the original inductor Lₛₑᵣᵢₑₛ at ωₒ. In this instance, the impedance range is increased by a factor of at least three (3) and up to five (5) times the original impedance value. Specifically, L₂=nLₛₑᵣᵢₑₛ=(3)(10×10⁻⁶)=30 μH, and C₃ is computed as:

C=1/(n−1)ωₒ²Lₛₑᵣᵢₑₛ=1/(3−1)((2π)(2×10⁶)²(10×10⁻⁶)=316.95 pF

Further,

ωₒ, Z=jωₒL;

$$\begin{matrix}( {ω}_{o} - Δω ) , Z = ( j ( {ω}_{o} - Δ ω ) 3 L ) - j ( \frac{2 {ω}_{o}^{2} L}{{ω}_{o} - Δ ω} ) ; \\ ( {ω}_{o} - Δω ) , Z = ( j ( {ω}_{o} + Δ ω ) 3 L ) - j ( \frac{2 {ω}_{o}^{2} L}{{ω}_{o} + Δ ω} ) ; \\ Accordingly , \vert Δ Z \vert = ( 6 Δ ω L ) + ( \frac{4 {ω}_{o}^{2} Δ ω L}{( {ω}_{o} + Δ ω ) ( {ω}_{o} - Δ ω )} ) .\end{matrix}$$

Computing for the impedances at 2 MHz +/−100 KHz, the result is

$$Z @ 2 MHz = - ( \frac{1}{( 2 π ) ( 2 {x10}^{6} ) ( 316.95 {x10}^{- 12} )} ) + ( ( 2 π ) ( 2 {x10}^{6} ) ( 30 {x10}^{6} ) ) = - 251.2 + 376.8 = 125.6 Ω$$

Z@2.1 MHz=−239.2+395.83=156.63 Ω

Z@1.9 MHz=−264.38+357.96=93.58 Ω

|ΔZ|=156.63−93.58=63.05 Ω

The sequence can be carried further to increase the impedance range. The general relationship between the inductance and the capacitance values is mathematically defined. Specifically, the value of the series inductor is nL, where n is a number greater than one (1) that approximately defines the desired impedance range improvement, and L is the inductance value in Henries. The value of the series capacitance is 1/(n−1)jωₒ²L, where ωₒ is the nominal frequency of operation for the matching network.

Additionally, the single shunt coupled capacitor “C” of the matching network 420 as shown in FIG. 4A, may be defined as having an impedance of Z and an absolute impedance range of |ΔZ|. In particular, for

ωₒ, Z=−j/ωₒC;

(ωₒ−Δω), Z=−/(ωₒ−Δω)C; and

(ωₒ+Δω), Z=−j/(ωₒ+Δω)C;

where ωₒ=2πfₒ at an initial frequency, Δω=a change in frequency, and L=inductance as measured in Henries. As such, the impedance range

$$\vert Δ Z \vert = \frac{2 Δ ω}{( {ω}_{o} + Δ ω ) ( {ω}_{o} - Δ ω ) C} .$$

By illustration, a 500 pf capacitor that is coupled parallel to a source 210 and load 250, where the source 210 illustratively provides a 2 MHz, +/−100 KHz signal, has an impedance of 159.24 ohms and an absolute impedance range of 15.97 ohms. Specifically,

1/jωₒC=1/((2π)(2×10⁶)(500×10⁻¹²))=159.24 ohms

ΔZ_{@1.9 MHZ and 2.1 MHZ}=1/((2π)(2×10⁶)(10×10⁻⁶)(2.1−1.9))=15.97 ohms.

As discussed above with regard to the series connected elements 222B and 224A of the exemplary embodiment shown in FIG. 2A, the absolute impedance range increases by at least a factor of (2n−1). For example, where n=2, the original capacitance decreases by a factor of 1/n=2, and the absolute impedance range increases by at least a factor of three ((2)(2)−1)=3. Specifically, the capacitance of capacitor

$${C}_{2} 222 A i s “ \frac{1}{2} C ”$$

and the shunt inductor L₃ 224B is selected to have the same impedance as the original impedance, illustratively using the single shunt capacitor (422A of FIG. 4A), where

$${L}_{3} = \frac{n - 1}{{ω}_{o} {C}_{shumt}} .$$

For:

$$\begin{matrix} {ω}_{o} , Z = \frac{- j}{{ω}_{o} C} ; \\ ( {ω}_{o} - Δ ω ) , Z = ( \frac{- j2}{{ω}_{o} - Δ ω} ) - j ( \frac{{ω}_{o}^{2} - Δ ω}{{ω}_{o}^{2} C} ) ; \\ ( {ω}_{o} + Δ ω ) , Z = ( \frac{- j2}{{ω}_{o} + Δ ω} ) - j ( \frac{{ω}_{o}^{2} + Δ ω}{{ω}_{o}^{2} C} ) ; \\ Accordingly , \vert ΔZ \vert = ( \frac{4 Δω}{( {ω}_{o} + Δω ) ( {ω}_{o} - Δω ) C} ) + ( \frac{2 Δω}{{ω}_{o}^{2} C} ) .\end{matrix}$$

Such results provides an increased impedance range of up to three times (3×) the impedance range of the original impedance range provided by a single inductor. By illustration, n is selected as equal to two (n=2), such that the capacitor C₂ 222A is provided with a capacitance value of

$$\frac{1}{n} {C}_{shunt} = \frac{1}{2} 500 {x10}^{- 12} = 250 p f$$

(i.e., one-half the original capacitance value (500 pf) of the illustrative single shunt capacitor Cₛₕᵤₙₜ described above. The value of the inductor L₃ 224B is calculated such that its absolute impedance is equal to the impedance of the original impedance, where

$${L}_{3} = \frac{n - 1}{{ω}_{o}^{2} {C}_{shunt}} = \frac{2 - 1}{{( ( 2 π ) ( 2 {x10}^{6} ) )}^{2} ( 500 {x10}^{- 12} )} = 12.67 μ H .$$

Computing for the impedances at 2 MHz +/−100 Khz, the result is

$$Z @ 2 MHz = {Z}_{C} + {Z}_{L} = - ( \frac{1}{( 2 π ) ( 2 {x10}^{6} ) ( 250 {x10}^{- 12} )} ) + ( ( 2 π ) ( 2 {x10}^{6} ) ( 12.67 {x10}^{- 6} ) ) = - 318.47 + 159.13 = 159.34 Ω$$

Similarly,

Z@2.1 MHz=−303.30+167.01=136.29 Ω

Z@1.9 MHz=−335.23+151.18=184.05 Ω

|ΔZ|=184.05−136.29=47.76 Ω

Thus, impedance range has increased by a factor greater than three (>3). In particular, the serial coupled elements (forming a parallel “leg”) between terminal 216 and ground 240 of the matching circuit shown in FIG. 2A has an impedance range of 47.76 ohms, as compared to a single capacitor, which has an impedance range of merely 15.97 ohms.

The sequence can be carried further to (increase the impedance range. The general relationship between the inductance and the capacitance values is mathematically defined. Specifically, the value of the parallel shunt capacitor is

$${C}_{2} = \frac{1}{n} C$$

and the shunt inductor

$${L}_{3} = \frac{n - 1}{{ω}_{o} {C}_{shumt}} ,$$

where n is a number greater than one (n>1) that approximately defines the desired impedance range improvement, and ωₒ is the nominal frequency of operation for the matching network.

For example, where n is selected to equal three (n=3), the capacitor C₂ 222A is

$$\frac{1}{3} {C}_{shunt} = ( 1 / 3 ) ( 500 pf ) = 166.67 pf ,$$

and the shunt inductor L₃ 224B is selected to have the same impedance as the original impedance, illustratively using the single shunt capacitor (422A of FIG. 4A), where

$${L}_{3} = \frac{n - 1}{{ω}_{o} {C}_{shumt}} = \frac{3 - 1}{{( ( 2 π ) ( 2 {x10}^{6} ) )}^{2} ( 500 {x10}^{- 12} )} = 25.35 μ H .$$

Computing for the impedances at 2 MHz +/−100 Khz, the result is

$$Z @ 2 MHz = {Z}_{C} + {Z}_{L} = - ( \frac{1}{( 2 π ) ( 2 {x10}^{6} ) ( 166.67 {x10}^{- 12} )} ) + ( ( 2 π ) ( 2 {x10}^{6} ) ( 25.35 {x10}^{- 6} ) ) = - 477.69 + 318.4 = 159.3 Ω$$

Similarly,

Z@2.1 MHz=−454.95+334.32=120.63 Ω

Z@1.9 MHz=−502.83+302.47=200.36 Ω

|ΔZ|=200.36−120.63=79.73 Ω

Thus, impedance range has increased by a factor greater than five (>5). In particular, the serial coupled elements (forming a parallel “leg”) between terminal 216 and ground 240 of the matching circuit shown in FIG. 2A has an impedance range of 79.73 ohms, as compared to a single capacitor, which has an impedance range of merely 15.97 ohms. Similar computations can be performed for situations where even greater match range capabilities are required to match the load 250 by increasing the multiplier factor “n”. For example, when the multiplier factor n is set to 4, the impedance range is increased by a factor greater than seven (i.e., 2n−1=(2×4)−1=7). When n=5, the impedance range is increased by a factor greater than nine (i.e., 2n−1=(2×5)−1=9), and so forth. In this manner a proper impedance range may be selected for the fixed matching network 230 based on actual or expected fluctuations of the load impedance, such as fluctuations in the impedance of a plasma load during semiconductor wafer processing.

FIG. 3 depicts a table 300 comparing the various embodiments of impedance matching networks of the present invention of FIGS. 2A-2H with respect to the various embodiments of prior art impedance matching networks of FIGS. 4A-4H. For each of the four types of original matching networks depicted in FIG. 3, each original matching network has a single series element and single shunt element as discussed above. Further, each of the respective wide range matching networks of the present invention comprises dual series elements and dual shunt elements. Moreover, a general relationship between the inductance and the capacitance values is mathematically defined. Specifically, the series inductor and series capacitor are related by a first mathematical relationship, while the shunt inductor and shunt capacitor are related by a second mathematical relationship.

For example, as discussed above with regard to the prior art embodiment of FIGS. 4A and 4C, the original matching circuit 420 includes a single series inductor Lₛₑᵣᵢₑₛ original and a single shunt capacitor Cₛₕᵤₙₜ_{_{—}}_{original}. The table 300 of FIG. 3 shows that each single frequency-dependent passive element is replaced by dual capacitive and inductive elements, as shown in FIGS. 2A and 2C. Specifically, the series inductor Lₛₑᵣᵢₑₛ_{_{—}}_{original} is replaced with an inductor Lₛₑᵣᵢₑₛ_{_{—}}_{new} having a value equal to a multiple value of the original series inductor, where Lₛₑᵣᵢₑₛ_{_{—}}_{new}=n Lₛₑᵣᵢₑₛ_{_{—}}_{original}, plus a capacitor having a value defined by a relationship Cₛₑᵣᵢₑₛ_{_{—}}_{new}=1/(n−1)ωₒ²Lₛₑᵣᵢₑₛ_{_{—}}_{original}. Similarly, the shunt capacitor Cₛₕᵤₙₜ_{_{—}}_{original} is replaced with a capacitor Cₛₕᵤₙₜ_{_{—}}_{new} having a value

$$\frac{1}{n} {C}_{shunt\_original}$$

plus an inductor having a value

$${L}_{shunt\_new} = \frac{n - 1}{{ω }_{o}^{2} {C}_{shunt\_original}} .$$

Where the original matching circuit 420 includes a single series capacitor Cₛₑᵣᵢₑₛ_{_{—}}_{original} and a single shunt capacitor Cₛₕᵤₙₜ_{_{—}}_{original}, as shown in the prior art embodiment of FIGS. 4B and 4D, the table 400 of FIG. 3 shows that each single frequency-dependent passive element is replaced by dual capacitive and inductive elements, as shown in FIGS. 2B and 2D. Specifically, the series capacitor Cₛₑᵣᵢₑₛ_{_{—}}_{original} is replaced with an inductor Lₛₑᵣᵢₑₛ_{_{—}}_{new} having a value equal to

$${L}_{series\_new} = \frac{n - 1}{ {ω }_{o}^{2} {C}_{series\_original}} ,$$

plus a capacitor having a value defined by a relationship

$${C}_{series\_new } = \frac{1}{n} {C}_{series\_original} .$$

Similarly, the shunt capacitor Cₛₕᵤₙₜ is replaced with a capacitor Cₛₕᵤₙₜ_{_{—}}_{new} having a value

$$\frac{1}{n} {C}_{shunt\_original} ,$$

plus an inductor having a value

$${L}_{shunt\_new} = \frac{n - 1}{{ω }_{o}^{2} {C}_{shunt\_original}}$$

as discussed above with regard to FIG. 2A.

Where the original matching circuit 420 includes a single series inductor Lₛₑᵣᵢₑₛ_{_{—}}_{original} and a single shunt inductor Lₛₕᵤₙₜ_{_{—}}_{original}, as shown in the prior art embodiment of FIGS. 4E and 4G, the table 300 of FIG. 3 shows that each single frequency-dependent passive element is replaced by dual capacitive and inductive elements, as shown in FIGS. 2E and 2G. Specifically, the series inductor Lₛₑᵣᵢₑₛ_{_{—}}_{original} is replaced with an inductor Lₛₑᵣᵢₑₛ_{_{—}}_{new} having a value equal to Lₛₑᵣᵢₑₛ_{_{—}}_{new}=nLₛₑᵣᵢₑₛ_{_{—}}_{original}, plus a capacitor having a value defined by a relationship

$${C}_{series\_new} = \frac{1}{( n - 1 ) {ω }_{o}^{2} {L}_{series\_original}} .$$

Similarly, the shunt capacitor Cₛₕᵤₙₜ is replaced with a capacitor Cₛₕᵤₙₜ_{_{—}}_{new} having a value

$$\frac{1}{( n - 1 ) {ω}_{{o}^{2}} {L}_{shunt\_original}} ,$$

plus an inductor having a value Lₛₕᵤₙₜ_{_{—}}_{new}=nLₛₕᵤₙₜ_{_{—}}_{original}.

Alternatively, where the original matching circuit 420 includes a single series capacitor Cₛₑᵣᵢₑₛ_{_{—}}_{original} and a single shunt inductor Lₛₕᵤₙₜ_{_{—}}_{original}, as shown in the prior art embodiment of FIGS. 4F and 4H, the table 300 of FIG. 3 shows that each single frequency-dependent passive element is replaced by dual capacitive and inductive elements, as shown in FIGS. 2F and 2H. Specifically, the series capacitor Cₛₑᵣᵢₑₛ_{_{—}}_{original} is replaced with a capacitor Cₛₑᵣᵢₑₛ_{_{—}}_{new} having a value equal to

$$\frac{1}{n} {C}_{series\_original} ,$$

plus an inductor having a value defined by a relationship

$${L}_{series\_new} = \frac{n - 1}{{ω }_{o}^{2} {C}_{series\_original}} .$$

Further, the shunt capacitor Cₛₕᵤₙₜ is replaced with a capacitor Cₛₕᵤₙₜ_{_{—}}_{new} having a value

$$\frac{1}{( n - 1 ) {ω}_{{o}^{2}} {L}_{shunt\_original}} ,$$

plus an inductor having a value Lₛₕᵤₙₜ_{_{—}}_{new}=nLₛₕᵤₙₜ_{_{—}}_{original}.

Using the inventive WRFT network as a matching network to couple power to a plasma in a semiconductor wafer processing chamber enables the network to maintain a match over a large range of load impedances. The selection of the component value combinations enables the matching network to be designed to operate over large process windows or narrow process windows. As such, the impedance range needed can be matched to the requirements of the reactor.

Although various embodiments that incorporate the teachings of the present invention have been shown and described in detail herein, those skilled in the art can readily devise many other varied embodiments that still incorporate these teachings.

What is claimed is:

1. A matching network for performing frequency tuned matching between a source and a load, comprising:
a first capacitor and first inductor, having fixed values, coupled in series from an input port to an output port;
a second capacitor and second inductor, having fixed values, coupled in series from one of said input port and output port to ground; and
where the input port is adapted to receive a variable frequency RF signal and the output port is adapted to be coupled to a time-variant load impedance.

2. The matching network of claim 1, wherein said first capacitor and first inductor values are related by a first mathematic relationship, and said second capacitor and second inductor values are related by a second mathematic relationship.

3. The matching network of claim 2, wherein said first mathematical relationship is the first inductor having a value NL, where N is a number greater than 1 and L is an inductance value in Henries, and the first capacitor having a value 1/(N−1)jωₒ²L, where too is a nominal frequency of operation for the matching network.

4. The matching network of claim 3, wherein said second mathematical relationship is the second capacitor having a value C/N, where C is a capacitance value in Farads, and the second inductor having a value (N−1)/jωₒ²C.

5. The matching network of claim 3, wherein said second mathematical relationship is the second capacitor having a value 1/(N−1)jωₒ²L, and the second inductor having a value NL.

6. The matching network of claim 2, wherein:
said first mathematical relationship is the first inductor having a value (N−1)/jωₒ²C, where N is a number greater than 1, ωₒ is a nominal frequency of operation for the matching network, and C is a capacitance value in Farads; and
said first capacitor having a value (1/N)C, where C is a capacitance value in Farads.

7. The matching network of claim 6, wherein said second mathematical relationship is the second capacitor having a value C/N, and the second inductor having a value (N−1)/jωₒ²C.

8. The matching network of claim 6, wherein said second mathematical relationship is the second capacitor having a value 1/(N−1)jωₒ²L, and the second inductor having a value NL, where L is an inductance value in Henries.

9. Apparatus for processing semiconductor wafers comprising:
a reactor having a pedestal for supporting a wafer and a plasma generating element for coupling RF energy to a gas to form a plasma proximate the wafer;
a variable frequency source, where the variable frequency source is dynamically tuned to maintain an impedance match between the variable frequency source and the plasma generating element; and
a matching network, coupled in series with said reactor and the plasma generating element, said matching network comprising:
a first capacitor and a first inductor, having fixed values, and connected in series between said reactor and the plasma generating element; and
a second capacitor serially connected to a second inductor, having fixed values, where said serially connected second capacitor and second inductor are shunted to ground with respect to one of said reactor and variable frequency source.

10. The apparatus of claim 9, wherein the plasma generating element is an electrode that forms a cathode in the reactor.

11. The apparatus of claim 9, wherein the electrode is a component of the pedestal.

12. The apparatus of claim 9, wherein the electrode is a component of a lid for the reactor.

13. The apparatus of claim 9, wherein the plasma generating element is an antenna positioned proximate the reactor.

14. The apparatus of claim 6 wherein said series connected capacitor and inductor are connected between the variable frequency source and the plasma generating element.

15. The apparatus of claim 11, wherein a value of the first capacitor and a value of the first inductor are related by a first mathematic relationship, and a value of the second capacitor and a value of the second inductor are related by a second mathematic relationship.

16. The apparatus of claim 15, wherein said first mathematical relationship is the first inductor having a value NL, where N is a number greater than 1 and L is an inductance value in Henries, and the first capacitor having a value 1/(N−1)jωₒ²L, where ωₒ is a nominal frequency of operation for the matching network.

17. The apparatus of claim 16, wherein said second mathematical relationship is the second capacitor having a value C/N, where C is a capacitance value in Farads, and the second inductor having a value (N−1)/jωₒ²C.

18. The apparatus of claim 16, wherein said second mathematical relationship is the second capacitor having a value 1/(N−1)jωₒ²L, and the second inductor having a value NL.

19. The apparatus of claim 15, wherein:
said first mathematical relationship is the first inductor having a value (N−1)/jωₒ²C, where N is a number greater than 1, ωₒ is a nominal frequency of operation for the matching network, and C is a capacitance value in Farads; and
said first capacitor having a value (1/N)C, where C is a capacitance value in Farads.

20. The apparatus of claim 19, wherein said second mathematical relationship is the second capacitor having a value C/N, and the second inductor having a value (N−1)/jωₒ²C.

21. The apparatus of claim 19, wherein said second mathematical relationship is the second capacitor having a value 1/(N−1)jωₒ²L, and the second inductor having a value NL, where L is an inductance value in Henries.

22. A method of increasing the impedance range of a matching network comprising:
replacing each single series component having a component value in an original matching network with a series connected first capacitor and first inductor, where the values of the series connected first capacitor and first inductor are related to the component value by a first mathematical relationship; and
replacing each single shunt component having a component value in an original matching network with a series connected second capacitor and second inductor, where the values of the series connected second capacitor and second inductor are related to the component value by a second mathematical relationship.

23. The method of claim 22, wherein the series connected first capacitor and first inductor are connected from an input port to an output port of the matching network;
and the series connected second capacitor and second inductor are shunted to ground with respect to one of said input port and said output port of said matching network.

24. The apparatus of claim 22, wherein said first mathematical relationship is the first inductor having a value NL, where N is a number greater than 1 and L is an inductance value in Henries, and the first capacitor having a value 1/(N−1)jωₒ²L, Where ωₒ is a nominal frequency of operation for the matching network.

25. The apparatus of claim 24, wherein said second mathematical relationship is the second capacitor having a value C/N, where C is a capacitance value in Farads, and the second inductor having a value (N−1)/jωₒ²C.

26. The apparatus of claim 25, wherein said second mathematical relationship is the second capacitor having a value 1/(N−1)jωₒ²L, and the second inductor having a value NL.

27. The apparatus of claim 22, wherein:
said first mathematical relationship is the first inductor having a value (N−1)/jωₒ²C, where N is a number greater than 1, ωₒ is a nominal frequency of operation for the matching network, and C is a capacitance value in Farads; and
said first capacitor having a value (1/N)C, where C is a capacitance value in Farads.

28. The apparatus of claim 27, wherein said second mathematical relationship is the second capacitor having a value C/N, and the second inductor having a value (N−1)/jωₒ²C.

29. The apparatus of claim 27, wherein said second mathematical relationship is the second capacitor having a value 1/(N−1)jωₒ²L, and the second inductor having a value NL, Where L is an inductance value in Henries.
